(19) United States
(12) Patent Application Publication
(10) Pub. No.: US 2001/0053583 A1
(43) Pub. Date: Dec. 20, 2001

(54) Shallow trench isolation formation process using a sacrificial layer

(76) Inventors: Simon Fang, Richardson, TX (US); Stanton P. Ashburn, McKinney, TX (US)

Correspondence Address: TEXAS INSTRUMENTS INCORPORATED, P O BOX 655474, M/S 3999, DALLAS, TX, 75265

(21) Appl. No.: 09/745,333

(22) Filed: Dec. 21, 2000

Related U.S. Application Data
(60) Provisional application No. 60/171,758, filed on Dec. 22, 1999.

(51) Int. Cl. H01L 21/76

(52) U.S. Cl. 438/424; 438/435; 438/430

(57) ABSTRACT

An embodiment of the instant invention is a method of forming an isolation structure within a semiconductor structure so as to provide isolation between two electronic devices, the method comprising: forming trenches in the semiconductor structure, the trenches having a top and a bottom, and a first portion of the trenches having a narrow bottom and a second portion of the trenches having an extended bottom; forming a filler material (108 of FIG. 4) in the trenches, the filler material filling the first portion of trenches to a first height and filling the second portion of trenches to a second height which is less than the first height thereby resulting in a stepped down portion of the filler material in the second portion of trenches; forming a planar layer on the filler material using a first material (304 of FIG. 4), the planar layer having a substantially planar top surface; removing the top portion of the planar material using a first removal agent which removes the first material more readily than the filler material, this step resulting in a substantially planar top surface formed substantially of the filler material over the first portion of the trenches and the first material over the second portion of the trenches; and removing the portions of the filler material and the first material which overlie the top of the trenches, the step of removing the portions of the filler material and the first material removes the filler material at about the same rate as the removal of the first material.

### FIELD OF THE INVENTION

The instant invention pertains to semiconductor device fabrication and processing and more specifically to a method of fabricating shallow trench isolation structures using a sacrificial layer to aid planarization.

### BACKGROUND OF THE INVENTION

Two consistent trends in the semiconductor device manufacturing industry include reducing the size of individual devices and reducing cost to fabricate these devices. In an effort to reduce the size of the individual devices, so as to increase the number of individual devices for a given chip size, many manufacturers have starting using shallow trench isolation (STI) structures to provide isolation between individual devices instead of field oxide (also known as LOCOS) structures. The reason for this is due, at least in part, to the fact that STI structures require less device area than does a LOCOS structure. However, STI structures, which provide good isolation between devices, can be difficult and costly to fabricate. In addition, the traditional approach to fabricating STI structures (illustrated in FIGS. 1a and 1b) has several problems.

The traditional approach to fabricating STI structures included the steps of growing a thermal pad oxide (which is shown as the structures under structures 106) on single-crystal silicon substrate 102 (or epitaxial silicon layer 102 which is formed over a single-crystal silicon substrate). Next a material, such as SiN, is deposited over pad oxide layer 101 and is patterned and etched to form structures 106 which can serve as a trench etch masking layer and as a chemical mechanical polish (CMP) stopping layer. Next, trenches are formed in the substrate 102 using masking layer 106 as a pattern. Next, a liner layer 104, typically a thermally grown oxide, is formed on the sides and bottom of the trenches. The liner layer 104 is necessary because it provides the benefits of a thermally grown oxide which provides a low defect Si/SiO2 interface, in addition to providing trench corner rounding. However, the trenches may be formed followed by the formation of liner layer 104. Next, polish-stop layer 106 is formed (typically by depositing silicon nitride and removing the portions of layer 106 that are formed in the trenches).

Layer 106 is provided so that when the STI filler material 108 is polished back, the polishing will terminate on this layer instead of continuing to polish thereby removing too much of the filler material 108 and portions of the STI wall structures. During the CMP process, it is necessary to remove all deposited STI filler material 108 from the surface of the CMP polish stopping layer 106. Thus, the polish time is determined by that necessary to clear this filler material 108, stopping on CMP polish stopping layer 106. However, a problem with this traditional method is that even though polish stopping layer 106 is formed between the isolation structures, in larger trench areas 109 excessive amounts of filler material 108 will undesirably be removed due to the pliable nature of the polishing pad. In other words, since the polishing pad is fairly flexible, in areas which do not have a lot of structures (such as area 109) the pad deforms down into the long trench area and removes excessive amounts of material. However, in the areas like area 111, i.e., large active areas or large arrays of minimum active pitch, the pad does not have much room to deform down into the trench areas. This phenomenon of removing excessive amounts of material during a polishing process is referred to as “dishing” and it is illustrated in FIG. 1b as regions 112. As can be seen in FIG. 1b, the dishing 112 of filler material 110 is much worse (much more material is removed from the trench) in region 109 as compared to region 111. This problem is exacerbated by the fact that the filler material tends to be quite conformal to the underlying structure which means that the height of filler material 108 in region 111 tends to be greater than the height of filler material 108 in region 109. Hence, there is tolerance for excess removal of filler material in region 109 as compared to region 111.

In an effort to solve this problem, several attempts to modify the traditional process have been made, but each of these modifications has problems. One approach at alleviating this problem is illustrated in FIG. 2. This approach starts off using the traditional formation technique as is illustrated in FIG. 1a, but prior to polishing filler material 108, a mask 202 is formed such that masking material remains over the trench structures. After the mask is formed, an etch-back process is performed so as to remove the portions of filler material 108 that lies between the trenches (illustrated as areas 204). After the masking layer 202 (which is preferably comprised of photoresist) is removed using standard semiconductor processing techniques, the polishing step is performed. The advantage of this methodology is that since there is less excess filler material to be removed in region 111, the amount of time required to remove this excess material will be less thereby resulting in less dishing in region 109. However, this process requires an extra masking step and this can be quite expensive. In fact, most semiconductor device manufacturers are continuously trying to reduce the number of masking steps required to fabricate devices to a bare minimum.

An alternative approach at solving the dishing problem involves depositing a thin layer of nitride over the entire device and then performing a polishing step. This approach assumes that the nitride layer will be cleared in area 111 before area 109 resulting in the quicker removal of filler material in region 111 as compared to region 109. However, this assumption does not seem to be correct. In controlled experiments, the nitride layer was cleared in region 109 at about the same time it was cleared from region 111. Hence, there is little apparent benefit to this approach.

Another alternative approach involves the use of a new slurry that removes oxide features at a much higher rate than nitride features. An example of this slurry and technique of using such a slurry can be found in co-pending patent applications Ser. No. 09/002,657 (TI-23590), and Ser. No. 09/004,358 (TI-23410) which are both incorporated herein by reference. This approach is still problematic because there still may be some dishing, and this approach imposes layout restrictions to minimize oxide variations within a wafer, from wafer to wafer, and from lot to lot.

In light of the above, a new polishing approach is needed which is not prohibitively expensive but which eliminates dishing.

### SUMMARY OF THE INVENTION

An embodiment of the instant invention is a method of forming an isolation structure within a semiconductor structure so as to provide isolation between two electronic devices, the method comprising: forming trenches in the semiconductor structure, the trenches having a top and a bottom, and a first portion of the trenches having a narrow bottom and a second portion of the trenches having an extended bottom; forming a filler material in the trenches, the filler material filling the first portion of trenches to a first height and filling the second portion of trenches to a second height which is less than the first height thereby resulting in a stepped down portion of the filler material in the second portion of trenches; forming a planar layer on the filler material using a first material, the planar layer having a substantially planar top surface; removing the top portion of the planar material using a first removal agent which removes the first material more readily than the filler material, this step resulting in a substantially planar top surface formed substantially of the filler material over the first portion of the trenches and the first material over the second portion of the trenches; and removing the portions of the filler material and the first material which overlie the top of the trenches, the step of removing the portions of the filler material and the first material removes the filler material at about the same rate as the removal of the first material. Preferably, the filler material is comprised of: silicon dioxide, PETOES, high-density plasma oxide, an oxynitride, or any combination of stack thereof, and the first material is comprised of polycrystalline silicon. The step of removing the top portion of the planar material is, preferably, performed by polishing the planar material using a first slurry, and the step of removing portions of the filler material and the first material is, preferably, performed by polishing the filler material and the first material using a second slurry.

### BRIEF DESCRIPTION OF THE DRAWINGS

FIGS. 1a-1b are cross-sectional views of a partially fabricated device which is fabricated using prior art methodology.

FIG. 2 is a cross-sectional view of a partially fabricated device which is fabricated using prior art methodology.

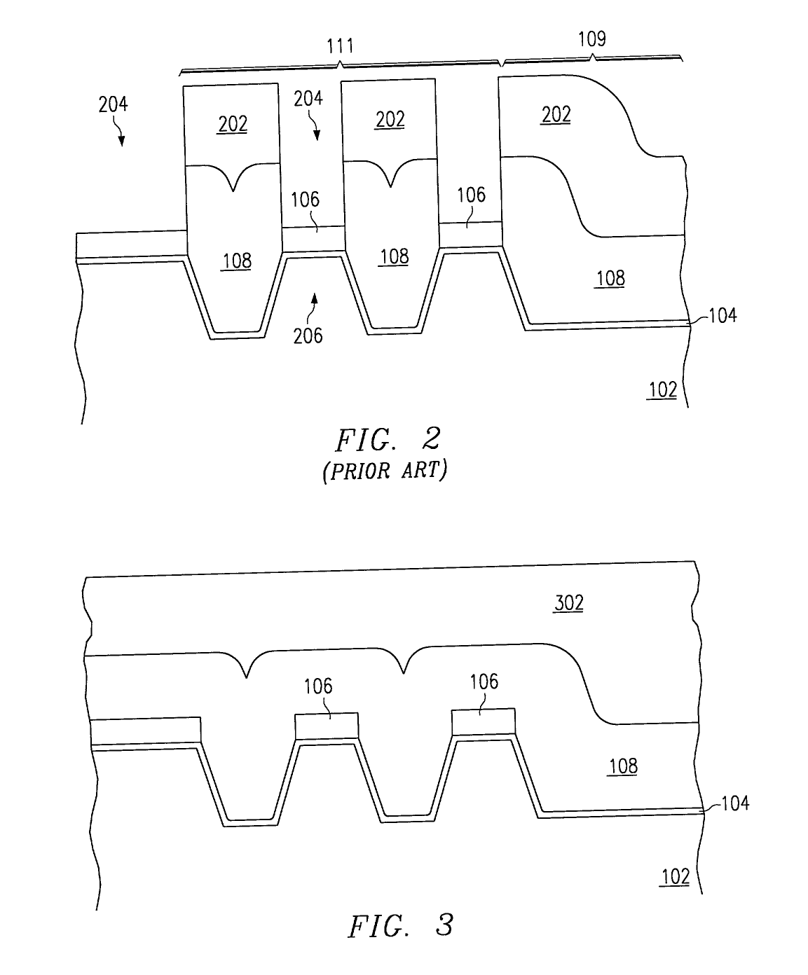

FIGS. 3-5 are cross-sectional views of a partially fabricated device which is fabricated using the methodology of one embodiment of the instant invention.

Similar reference numerals are used throughout the figures to designate like or equivalent features. The figures are not drawn to scale. They are merely provided to illustrate the affect of the method of the instant invention.

### DETAILED DESCRIPTION OF THE DRAWINGS

While the following description of the instant invention is centered around an oxide filler and a polycrystalline silicon (also referred to as “poly” or “polysilicon”) polishing over-layer, other materials can be used so long as the filler material has the necessary properties with respect to isolation structures and the polishing material is one in which it can be readily removed in a polishing operation which would not readily remove the filler material. The polishing over-layer must also be easily removed in another polishing operation which will as readily remove the filler material. Furthermore, while the following description of the instant invention is centered around chemical-mechanical polishing, a blanket etch-back process or other blanket removal process may be used instead of or in conjunction with the CMP operation.

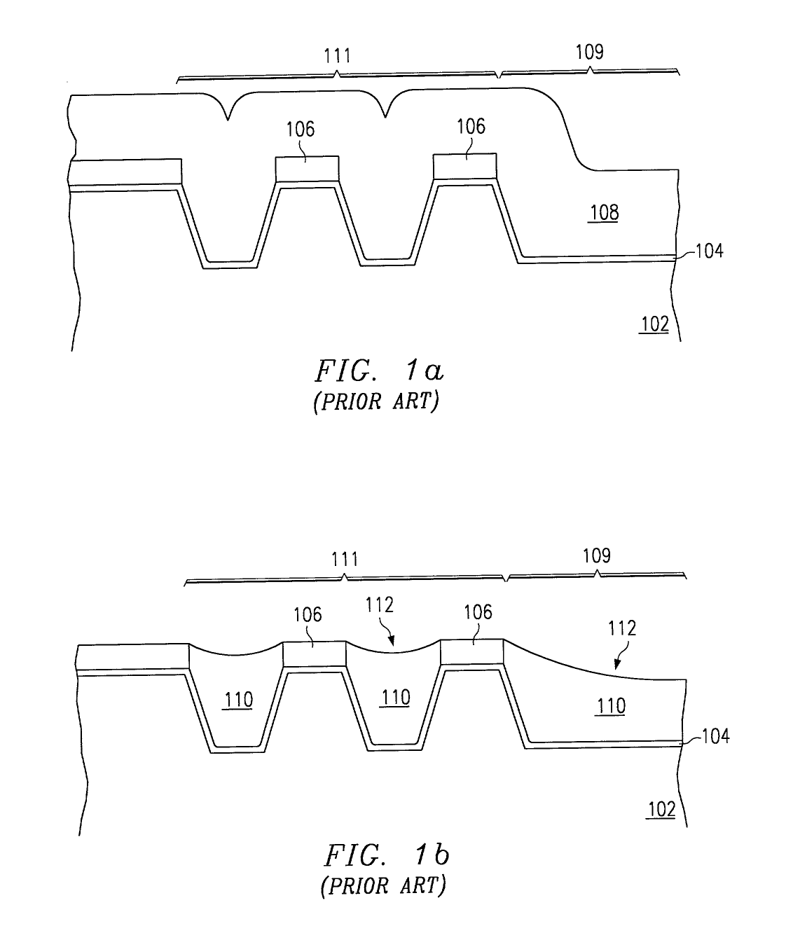

As is illustrated in FIG. 1a, structure 102 may be comprised of either a single-crystal silicon substrate or an epitaxial silicon layer formed on a single-crystal silicon substrate. Structure 102 will simply be referred to as “substrate 102” in the following description, but it could be either of these structures. After the trenches are formed in substrate 102, a liner layer 104 is formed. Preferably, liner layer 104 is a thermally grown silicon dioxide layer which is around 15 to 30 nm thick (more preferably around 18 to 27 nm thick). However, liner layer 104 may be comprised of any type of oxide, nitride, oxide/nitride stack, oxynitride, or any other insulating material so long as it does not provide an electrical leakage path around the trench. Polishing stopping layer 106 is formed and patterned/etched so as to be removed from the trench areas. However, as is described above, a pad oxide and layer 106 may be formed prior to the formation of the trenches and used as the masking layer to form the trenches. After the trenches are formed, liner layer 104 would then be grown on the sidewalls and bottoms of the trenches.

Preferably, polishing stopping layer 106 is comprised of around 150 to 250 nm thick (more preferably around 200 nm thick) silicon nitride, but it may be comprised of any material which is not appreciably removed in the standard removal step that is used to polish (or etch) back filler material 108. Filler material is formed, next. Preferably, filler material 108 is comprised of an APCVD ozone TEOS which is around 600 to 700 nm thick (preferably around 650 nm thick) for trenches that are on the order of 200 to 500 nm deep (preferably around 350 nm deep). In other words, it is desirable to form filler 108 to a thickness such that the height of filler material in region 109 is around 50 to 150 nm (more preferably around 100 nm) higher then the top of polishing stopping layer 106. Filler material 108 may be (additionally or instead of) comprised of PETEOS, high-density plasma oxide, an oxynitride, or any other dielectric material which provides beneficial isolation properties and which is easily formed and uniformly removed.

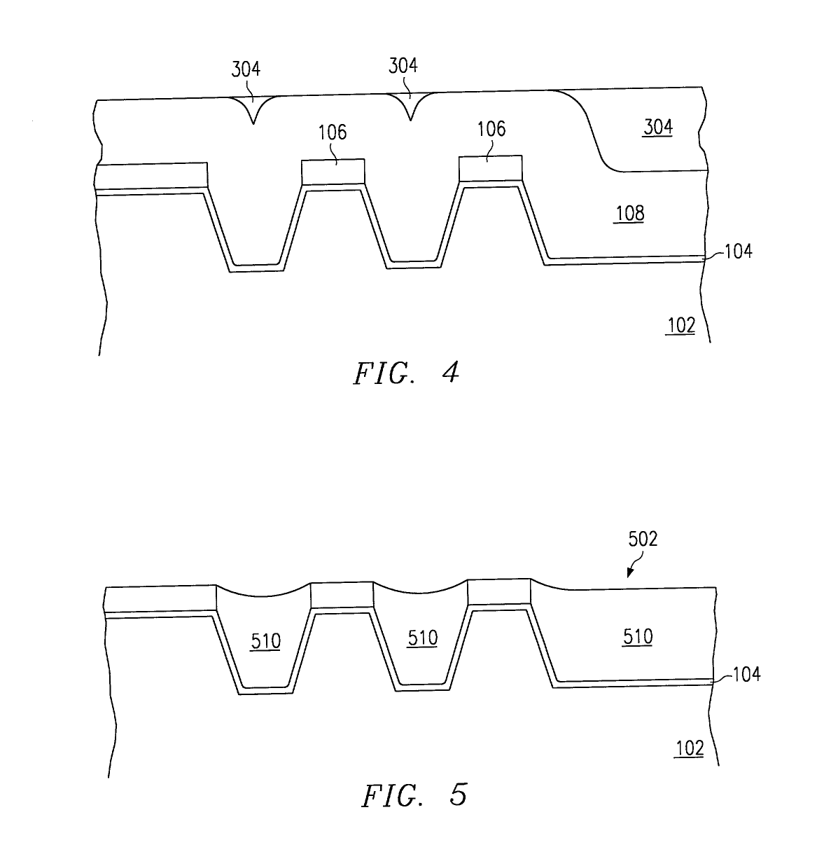

Referring to FIG. 3, over-layer 302 is formed in this method of the instant invention. In order for this method of the instant invention to work properly, over-layer 302 should have the following characteristics: when formed, it should remain at a relatively constant height (hence, as is shown in FIG. 3, it should not be conformal to filler 108—after formation it should provide a very planar surface); it should be readily removed in either a polishing step or a blanket etch-back process which will not readily remove filler material 108 (preferably the removal rate of over-laying layer 302 as compared to filler material 108 should be any where between 500:1, 250:1, 100:1 or as low as 50:1); and it should be able to be removed in another polishing or blanket etch-back process so that the removal rate of the over-laying layer 302 as compared to that of the filler material 108 is about equal (preferably on the order of 0.75:1 to 1.25:1—preferably, 1:1, respectively). In this embodiment of the instant invention, over-laying layer 302 is comprised of 500 to 1500 nm thick polysilicon. Preferably, over-layer 302 is formed by chemical vapor deposition (CVD), which may or may not be plasma-enhanced (PE).

Referring to FIG. 4, a polishing or blanket etch-back step is performed which removes over-laying layer 302 at a much faster rate then it removes filler material 108. Preferably, the removal rate of the over-laying layer 302 to filler material 108 is around 50:1 (more preferably greater than 100:1, even more preferably greater than 250:1, and most preferably greater than around 500:1). In one embodiment of the instant invention, over-laying layer 302 is removed using CMP and a Rodel SDE-3000 slurry which removes around 200 parts of polysilicon to every 1 part of oxide. However, any slurry or etchant can be used so long as it has the removal properties discussed above. The result of this process step is shown in FIG. 4. Note, the planar top surface where the filler material provides the top surface in the densely populated region 111 and the over-laying layer portions 304 form the planar surface in the sparsely populated region 109. This is one of the advantages of the instant invention.

Referring to FIG. 5, a polishing or blanket etch-back is performed which preferably removes equal parts of over-laying layer 302 and filler material 108. In one embodiment of the instant invention, a CMP process is performed using a Cabot Semisperse SS11 or SS12 slurry. The removal rate of polysilicon to oxide for this process is around 1.5:1, respectively. The resultant structure is shown in FIG. 5. Some dishing 502 may occur, but using the methodology of the instant invention, it will be very small. Preferably, if there is any dishing using the method of the instant invention, it will be no more than 10 to 50 nm deep in filler material 510.

Although specific embodiments of the present invention are herein described, they are not to be construed as limiting the scope of the invention. Many embodiments of the present invention will become apparent to those skilled in the art in light of methodology of the specification. The scope of the invention is limited only by the claims appended.

What we claim is:

1. A method of forming an isolation structure within a semiconductor structure so as to provide isolation between two electronic devices, said method comprising:
forming trenches in said semiconductor structure, said trenches having a top and a bottom, and a first portion of the trenches having a narrow bottom and a second portion of said trenches having an extended bottom;
forming a filler material in said trenches, said filler material filling said first portion of trenches to a first height and filling said second portion of trenches to a second height which is less than said first height thereby resulting in a stepped down portion of said filler material in said second portion of trenches;
forming a planar layer on said filler material using a first material, said planar layer having a substantially planar top surface;
removing the top portion of said planar layer using a first removal agent which removes said first material more readily than said filler material, this step resulting in a substantially planar top surface formed substantially of said filler material over said first portion of said trenches and said first material over said second portion of said trenches; and
removing the portions of said filler material and said first material which overlie said top of said trenches, said step of removing the portions of said filler material and said first material removes said filler material at about the same rate as the removal of said first material.

2. The method of claim 1, wherein said filler material is comprised of: silicon dioxide, PETOES, high-density plasma oxide, an oxynitride, or any combination of stack thereof.

3. The method of claim 1, wherein said first material is comprised of polycrystalline silicon.

4. The method of claim 1, wherein said step of removing the top portion of said planar material is performed by polishing said planar material using a first slurry.

5. The method of claim 1, wherein said step of removing portions of said filler material and said first material is performed by polishing said filler material and said first material using a second slurry.
